(19) United States
(12) Patent Application Publication
(10) Pub. No.: US 2007/0096955 A1
(43) Pub. Date: May 3, 2007

(54) MULTIPLE OUTPUT CONVERTER AND CONTROL IC

(75) Inventor: David New, Arlington, TN (US)

Correspondence Address: OSTROLENK FABER GERB & SOFFEN, 1180 AVENUE OF THE AMERICAS, NEW YORK, NY, 100368403, US

(73) Assignee: International Rectifier Corporation, El Segundo, CA (US)

(21) Appl. No.: 11/551,054

(22) Filed: Oct. 19, 2006

Related U.S. Application Data
(60) Provisional application No. 60/731,206, filed on Oct. 28, 2005.

(51) Int. Cl. H03M 7/00

(52) U.S. Cl. 341/50

(57) ABSTRACT

A multiple output voltage converter in accordance with an embodiment of the present application includes a controller and a plurality of conversion devices controlled by the controller and operable to convert an input voltage into an output voltage to provide a plurality of final output voltages that are applied to a plurality of electrical loads. Alternatively, a multiple output voltage converter in accordance with another embodiment of the present invention includes a controller, at least one first stage conversion device controlled by the controller and operable to receive an input voltage and to provide a first output of a first voltage value and a plurality of second stage conversion devices controlled by the controller and operable to provide a plurality of second output voltages to be supplied to a plurality of electrical loads, wherein each second stage conversion device of the plurality of conversion devices receives the first output voltage from the at least one first stage conversion device as an input.

### CROSS REFERENCE TO RELATED APPLICATIONS

The present application claims the benefit of and priority to U.S. Provisional Patent Application Ser. No. 60/731,206 entitled MULTI-OUTPUT CONVERTER CONTROL IC filed on Oct. 28, 2005, the entire contents of which are hereby incorporated by reference herein.

### BACKGROUND

1. Field of the Invention

The present invention relates to switching converters.

2. Related Art

Multi-phase converters, for example, such as International Rectifier's X Phase series of converters, have a control circuit which provides control signals to control the turning on of a plurality of output stage converters. The output stage converters are often controlled in a phase sequence so that the output stage converters are turned on in a sequence. In this way, the power demands of the load are supplied from the plurality of output stage converters. One example of such a multi-phase converter is a multi-phase buck converter in which each of the output stages comprise buck converters providing an output voltage. Such converters are commonly used to provide a high current to a load, for example, for use in a server, lap top or notebook microprocessor.

One example of a multiple-phase converter is given in U.S. Pat. No. 6,806,154. Another example of such a multi-phase converter is described in U.S. Pat. No. 6,806,689.

Multiple phase converters typically provide a single output voltage, however, it would be advantageous to provide a voltage converter comprising a plurality of converters, e.g., multi-phase converters, controlled from a converter control circuit to provide multiple outputs that may be applied to different loads.

FIG. 1A shows a typical prior art multi-phase converter. A controller 1 provides control signals and receives control signals from phase control circuits 2, 3 . . . n. Typically the control signals are provided to control the stage converters C1, C2 . . . CN. The output of stage converters C1, C2 . . . CN are typically half bridges coupled to a DC bus voltage Vin and ground. The switched nodes V_{S1}, V_{S2} . . . V_{SN} are coupled through the respective output inductors L1, L2 . . . LN to an output capacitor Co at which the single output voltage Vout is developed. Typically, each of the output stage converters is controlled so that the control transistor (high side transistor MS) is turned on at a different time so that each converter contributes to the load current in a phased time sequence, hence the name multi-phase converter.

### SUMMARY

A multiple output voltage converter in accordance with an embodiment of the present application includes a controller and a plurality of conversion devices controlled by the controller and operable to convert an input voltage into an output voltage to provide a plurality of final output voltages that are applied to a plurality of electrical loads.

A multiple output voltage converter in accordance with another embodiment of the present invention includes a controller, at least one first stage conversion device controlled by the controller and operable to receive an input voltage and to provide a first output of a first voltage value and a plurality of second stage conversion devices controlled by the controller and operable to provide a plurality of second output voltages to be supplied to a plurality of electrical loads, wherein each second stage conversion device of the plurality of conversion devices receives the first output voltage from the at least one first stage conversion device as an input.

A multiple output voltage converter in accordance with a third embodiment of the present invention includes a controller, at least one first stage conversion device controlled by the controller and operable to receive an input voltage and to provide a first output of a first voltage value, a plurality of second stage conversion devices controlled by the controller and operable to provide a plurality of second output voltages, to be supplied to a plurality of electrical loads, wherein each second stage conversion device of the plurality of conversion devices receives the first output voltage from the at least one first stage conversion device as an input and further comprising a further conversion device controlled by the controller and connected directly to the input voltage to provide a third output voltage to be supplied to one of the plurality of electrical loads, such that the further conversion device provides for single stage conversion of the input voltage.

The converter according to the present invention, particularly a two or multiple stage converter, provides advantage over the prior art. For example, with a two or more stage converter, the voltage is converted in stages, leading to reduced switching losses as compared to a converter wherein the voltage conversion is performed in a single stage. For example, in a buck converter when the voltage is reduced in at least two stages, the total switching losses may be less than for a single stage converter where the voltage is converted in a single (including multiphase) stage.

### BRIEF DESCRIPTION OF DRAWINGS

FIG. 1 illustrates a multiple output converter control integrated circuit controlling a plurality of multi-phase stage converters in accordance with an embodiment of the present invention.

FIG. 1A shows a typical prior art multi-phase converter;

FIG. 2 illustrates a multiple output converter control integrated circuit controlling a plurality of multi-phase stage converters in accordance with another embodiment of the present invention.

FIG. 3 illustrates a multiple output converter control integrated circuit controlling a plurality of multi-phase stage converters in accordance with a third embodiment of the present invention.

### DETAILED DESCRIPTION

The present invention is directed to a multiple output converter controlled by a control integrated circuit such that the converter provides multiple outputs for connection to different loads. In accordance with one embodiment of the present invention, each of the outputs provides a different voltage to the different loads. Naturally, if desired, the same voltage can be provided to each of the different loads or some voltages can be the same or different.

As noted above, conventional multi-phase converters provide a single output voltage from the multiple phases. In contrast, in the present invention, the multiple outputs are used to supply a plurality of loads. The converter of the present application may be a single stage converter or a two or more stage converter.

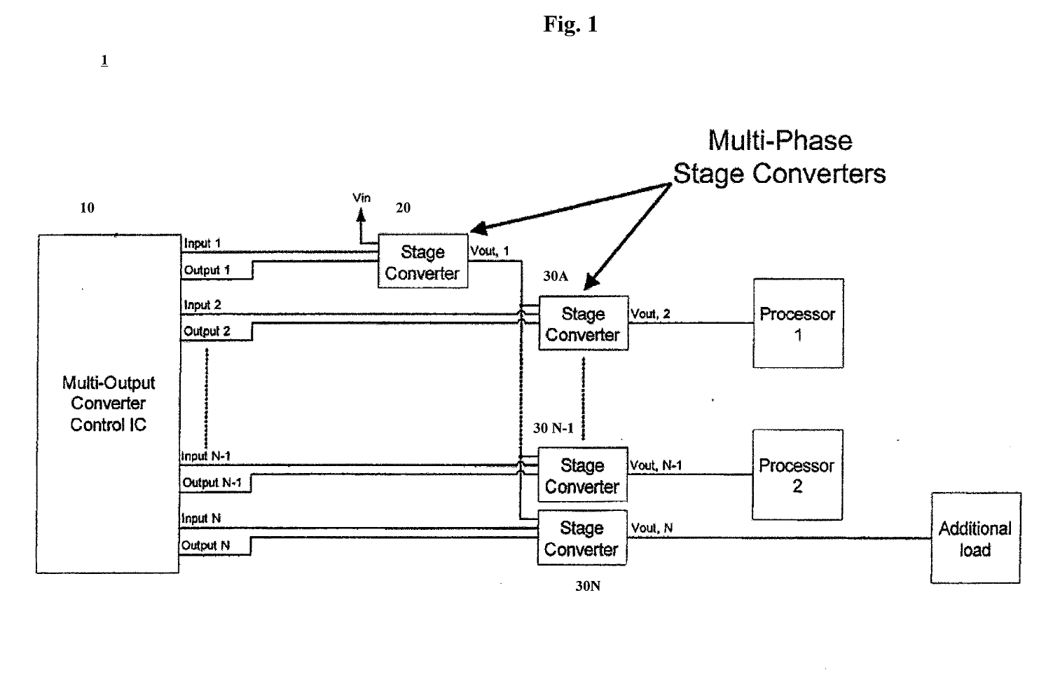

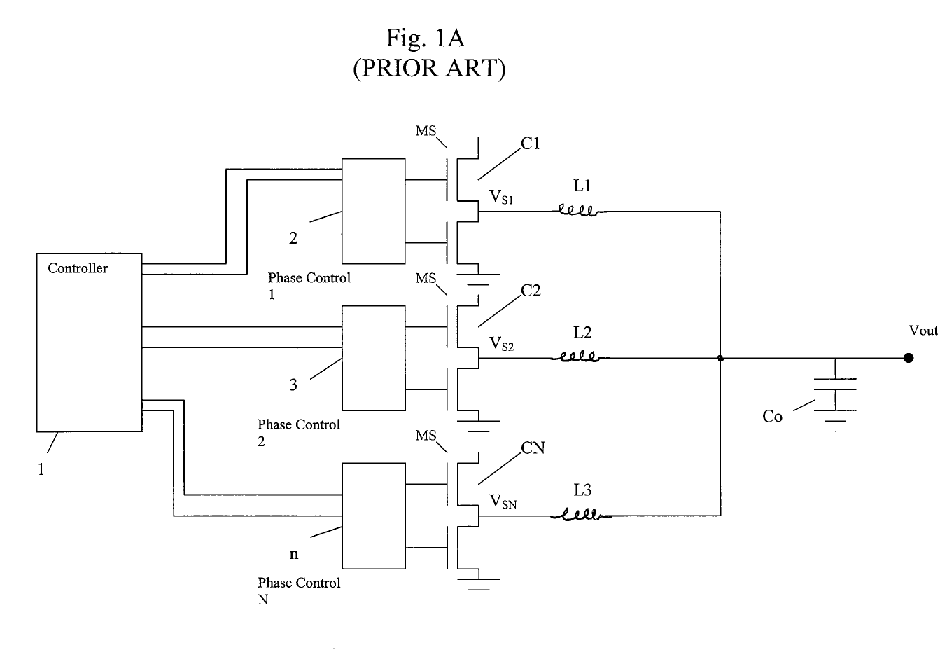

FIG. 1 illustrates a two stage, multiple output converter 1 in accordance with an embodiment of the present invention. The converter 1 preferably includes a converter controller 10, at least one first stage conversion device 20 and at least one, and preferably a plurality of second stage conversion devices 30A-30N. In the embodiment illustrated in FIG. 1, each of the second stage conversion devices 30A-30N includes an output Vout, 2 to Vout, N for connection to a plurality of different electrical loads. These different loads are illustrated in FIG. 1 as Processor 1, Processor 2 and other “additional loads”, however, the loads may take most any form and need not be processors as specifically illustrated in FIG. 1.

As illustrated in FIG. 1, the first stage conversion device 20 is provided with the input voltage Vin. The first stage conversion device 20 is also connected to the controller 10 via a first input/output pair, including Input 1 and Output 1. The first input/output pair allows the controller 10 to control the conversion device 20 to convert the input voltage Vin into a first output voltage Vout, 1. The input voltage Vin is a DC voltage and the first output voltage Vout, 1 is also a DC voltage for a buck converter, typically a lower DC voltage than the input voltage. The specific level of the output voltage Vout, 1 will depend on the control (typically PWM) provided by the controller 10.

The first stage conversion device 20 may be implemented in any desired form. For example the first stage conversion device 20 may be a buck converter. However, any suitable means for providing voltage conversion may be used in the first stage conversion device 20.

FIG. 1 also illustrates the controller 10 as an integrated circuit (IC). While this is a preferred implementation of the controller, the controller 10 may be implemented with any appropriate circuitry. As illustrated, the controller 10 has a plurality of input/output control pairs. As noted above, the first pair, including Input 1 and Output 1 is used to control the first stage conversion device 20, as mentioned above. The additional input/output pairs may be used to control the second stage conversion devices 30A-30N, for example.

The first output Vout, 1 is preferably connected to each of the second stage conversion devices 30A-30N. These second stage conversion devices are also controlled by the controller 10, via the additional input/output pairs Input 2/Output 2 to Input N/Output N, respectively, in a manner similar to that described above with reference to the first stage conversion device 20. The multiple outputs, Vout, 2 to Vout, N of the of the multiple output converter device 1 preferably correspond to the outputs of each of the second stage conversion devices 30A-30N. As shown, the output Vout, 2 of conversion device 30A is provided to Processor 1, the output Vout, N−1 from conversion device 30N−1 and so on. In a preferred embodiment, the outputs Vout 2, Vout, N−1, etc. each provide a different voltage to the Processor 1, the Processor 2, etc.

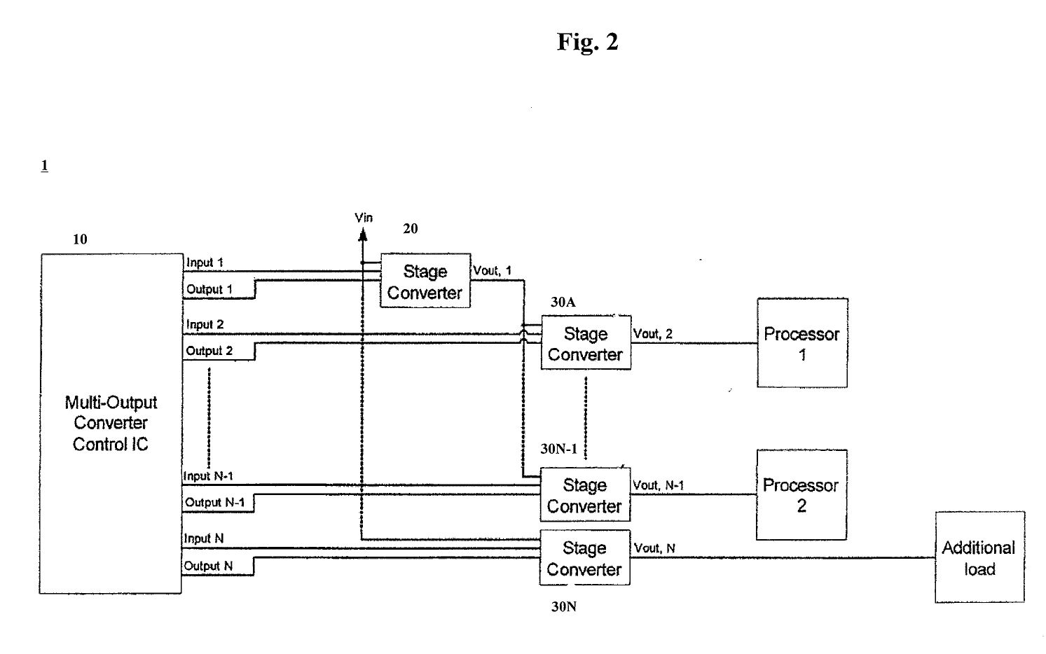

FIG. 2 shows an alternative embodiment of a multiple output converter and control integrated circuit 1 which utilizes both single stage and multiple stage converter architecture. The converter of FIG. 2 is similar to that of FIG. 1, except that the conversion device 30N is not connected to the first output, Vout, 1, of the first stage conversion device 20. Instead, this selected conversion device 30N is connected directly to the input voltage Vin. In this manner, the conversion device 30N acts as a single stage converter while the conversion devices 30A-30N−1 act as two stage converters in a manner similar to that described above with regard to FIG. 1.

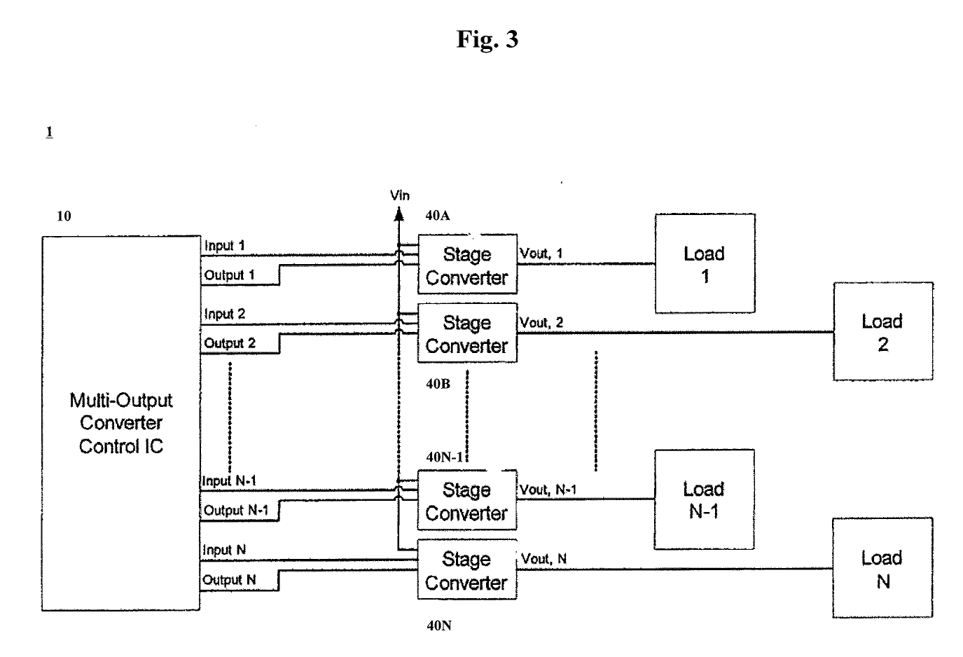

FIG. 3 shows a third embodiment of a multiple output converter 1 that uses a single stage architecture. In this embodiment all of the conversion devices 40A-40N are single stage. The converter 1 includes a controller 10 that controls each of the conversions devices 40-40A in a manner similar to that described above. That is, the controller 10 includes input/output pairs for connection to each of the conversion devices 40A-40N. The input voltage Vin is preferably provided to each of the conversion devices 40A-40N and each of the conversion devices provides an output, Vout, 1 to Vout, N to be provided to different loads, such as Load 1, Load 2, etc. As noted above, each of the outputs may provide a different voltage to the respective loads. If desired, each of the outputs may provide the same voltage or some may provide the same voltage. The output voltages from each of the conversion devices 40A-40N are determined based on of the control provided by the controller 10.

While the present application describes first stage conversion device 20, second stage conversion devices 30A-30N and other conversion devices 40A-40N, all of these conversion devices may be implemented in a common manner. For example, all of the conversion devices may be buck converters. Of course, if desired any other form of voltage conversion may be applied, if desired. For example, it may be useful to use voltage dividing circuits.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

1. A multiple output voltage converter comprising:
a controller; and
a plurality of conversion devices controlled by the controller and operable to convert an input voltage into an output voltage to provide a plurality of final output voltages that are applied to a plurality of electrical loads.

2. The multiple output converter device of claim 1, wherein the controller further comprises a plurality of input/output pairs of connections, wherein each input/output pair of connections is operable to control one of the plurality of conversion devices.

3. The multiple output converter device of claim 2, wherein each of the conversion devices is a buck converter.

4. The multiple output converter device of claim 1, wherein the plurality of final output voltages have different values.

5. The multiple output converter device of claim 1, wherein each of the conversion devices is a multi-phase converter.

6. A multiple output converter comprising:
a controller;
at least one first stage conversion device controlled by the controller and operable to receive an input voltage and to provide a first output of a first voltage value;
a plurality of second stage conversion devices controlled by the controller and operable to provide a plurality of second output voltage to be supplied to a plurality of electrical loads, wherein each second stage conversion device of the plurality of conversion devices receives the first output voltage from the at least one first stage conversion device as an input.

7. The multiple output converter device of claim 6, further comprising a further conversion device controlled by the controller and connected directly to the input voltage to provide a third output voltage, such that the further conversion device provides for single stage conversion of the input voltage.

8. The multiple output converter device of claim 7, wherein the controller further comprises a least one input/output pair of connections for the first stage conversion device, each of the plurality of second stage conversion devices and the further conversion device to allow for control of the conversion devices.

9. The multiple output converter device of claim 8, wherein each of the first stage, second stage and further conversion devices is a buck converter.

10. The multiple output converter device of claim 9, wherein each second output of the multiple second outputs provided by the second stage conversion devices and the third output voltage of the further conversion device are provided to different electrical loads.

11. The multiple output converter device of claim 6, wherein the first and second stage conversion devices are multi-phase converters.

12. The multiple output converter device of claim 7, wherein the first stage, second stage and further conversion devices are multi-phase converters.

13. A multiple output converter comprising:
a controller;
at least one first stage conversion device controlled by the controller and operable to receive an input voltage and to provide a first output of a first voltage value;
a plurality of second stage conversion devices controlled by the controller and operable to provide a plurality of second output voltages to be supplied to a plurality of electrical loads, wherein each second stage conversion device of the plurality of conversion devices receives the first output voltage from the at least one first stage conversion device as an input; and
a further conversion device controlled by the controller and connected directly to the input voltage to provide a third output voltage to be supplied to one of the plurality of electrical loads, such that the further conversion device provides for single stage conversion of the input voltage.

14. The multiple output converter of claim 13, wherein the first stage, second stage and further conversion devices are multi-phase conversion devices.
